(19) United States
(12) Patent Application Publication
(10) Pub. No.: US 2026/0291093 A1
(43) Pub. Date: Sep. 24, 2026

(54) Option Module Fastener Detection

(71) Applicant: Dell Products L.P., Round Rock, TX (US)

(72) Inventors: Jennifer Violet Davis, Leander, TX (US); Jacob H. Lavallo, Austin, TX (US); Ming-Chia Chuang, Taipei (TW)

(73) Assignee: Dell Products L.P., Round Rock, TX (US)

(21) Appl. No.: 19/085,869

(22) Filed: Mar. 20, 2025

(51) Int. Cl. H01R 12/70; G06F 1/184; H01R 12/71

(52) U.S. Cl. CPC H01R 12/7047; G06F 1/184; H01R 12/716

(57) ABSTRACT

A system to ensure secure coupling and proper electrical interfacing between the module and a motherboard. A module for the IHS comprises a circuit board having a first side and a second side opposite the first side; a hole in the circuit board; a first contact adjacent to the hole; a second contact adjacent to the hole and spaced apart from the first contact; and a module connector attached to a bottom surface of the circuit board, the module connector having a plurality of pins or sockets. The first contact is electrically connected to a selected pin or socket on a module connector. A fastener extends through the hole. When the fastener is touching both the first contact and the second contact, the selected pin or socket is electrically connected to ground when the head end is touching both the first contact and the second contact.

### BACKGROUND

Information Handling Systems (IHS) generally process, compile, store, and/or communicate information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use. In addition, information handling systems may include a variety of hardware and software components that may be configured to process, store, and communicate information and may include one or more computer systems, data storage systems, and networking systems.

IHSs are generally built from a wide variety of components. Selecting components to include within an information handling system helps end users target the capabilities of the information handling system for planned tasks. Typically, an information handling system has a motherboard that couples to a chassis to support communication between information handling system components. A typical motherboard is a printed circuit board (PCB) that has one or more central processing unit (CPU) sockets to accept one or more CPUs for executing instructions. The CPU sockets interface through the motherboard with memory sockets that hold memory for storing information in support of executing instructions, such as DIMM sockets that hold DRAM modules. The motherboard can interface with a variety of other components, such as an embedded controller, a network interface module, a graphics processor and other types of chipset components supported by the motherboard that perform processing functions. Generally, components interface through the motherboard using standardized communications links, such as a PCI or PCIe bus.

In some instances, processing functions are performed by components located off the motherboard, such as components supported by daughter boards or option modules. Option modules typically include a PCB with function-specific components, such as graphics components or network communication components. Option modules generally include an interface that provides communication with the motherboard through the motherboard's communications link, such as a PCI or PCIe bus. By distributing functions to option modules, an IHS provides end users with greater flexibility for the selection of components. For example, a graphics subsystem built on an option module will typically provide more effective graphics processing than the graphics components included with a chipset coupled to a motherboard. As another example, a server adjusts to interface with local area networks and/or storage networks by inserting appropriate option modules for the desired interfaces. One difficulty with the use of option modules is ensuring that the option modules will securely couple to the motherboard with proper electrical interfaces and without inducing forces on connections or interfaces to the motherboard.

### SUMMARY

In one embodiment, a module for an information handling system comprises a circuit board having a first side (top) and a second side (bottom) opposite the first side; a hole in the circuit board, the hole having a first opening through the first side of the circuit board; a first contact adjacent to one side of the hole opening; a second contact adjacent to the opposite side of the hole opening and spaced apart from the first contact; and a module connector attached to a bottom surface of the circuit board, the module connector having a plurality of pins or sockets. The first contact of the hole opening is electrically connected to a selected pin or socket on a module connector. A fastener extends through the hole. The fastener has a head end located on the first side of the circuit board. When the head end is touching both the first contact and the second contact adjacent to the hole opening, an electrical short is created between the first contact and the second contact. The selected pin or socket is electrically connected to ground when the head end is touching both the first contact and the second contact.

In another embodiment, an information handling system comprises a motherboard having a motherboard connector and a module. The module comprises a circuit board having a first (top) side and a second (bottom) side opposite the first side and a hole through the circuit board. The hole has a first opening on the first side of the circuit board. A first contact is positioned adjacent to the hole opening. A second contact is positioned adjacent to the opposite side of the hole opening and is spaced apart from the first contact. A module connector is coupled to the motherboard connector, wherein the first contact is electrically connected to a selected pin or socket on the module connector.

The motherboard connector has a fastener-detect socket or pin that is adapted to electrically connect to the selected pin or socket on the module connector. A fastener-detect circuit is coupled to the fastener-detect socket or pin and is configured to hold the fastener-detect socket or pin at a high signal voltage. A fastener extends through the hole. The fastener has a head end located on the first (top) side of the circuit board. When the head end is touching both the first contact and the second contact, the head end causes an electrical short between the first contact and the second contact. The selected pin or socket may be electrically connected to ground when the head end is touching both the first contact and the second contact. The fastener may have a threaded end opposite the head end, adapted to attach the module connector to the motherboard connector.

In another embodiment, an IHS comprises a motherboard connector mounted on a motherboard. The motherboard connector has a first detection contact. An IHS component includes a component connector having a second fastener-detect contact. The second detection contact is adapted to electrically connect to the first detection contact on the motherboard connector. A component fastener has a head end. The component fastener is disposed within a hole in the IHS component and is configured to attach the component connector to the motherboard connector. A first fastener contact is positioned adjacent to the hole and is electrically coupled to the second contact. A second fastener contact is positioned adjacent to the hole and spaced apart from the first contact. The second fastener contact is electrically connected to ground, wherein the first detection contact is electrically connected to ground when the head end is touching both the first fastener contact and the second fastener contact. The IHS may further include a motherboard controller configured to monitor a signal voltage level on the first detection contact.

These and other features will be more clearly understood from the following detailed description taken in conjunction with the accompanying drawings and claims.

### BRIEF DESCRIPTION OF THE DRAWINGS

Having thus described the invention in general terms, reference will now be made to the accompanying drawings, which are not necessarily drawn to scale, and wherein:

FIG. 1 is a partially exploded view of an option module according to an example embodiment.

FIG. 2 illustrates a portion of an IHS chassis.

FIG. 3 illustrates a cross section view of an option module being installed in a chassis.

FIG. 4 is an isometric view of the inside of a chassis showing an option module installed.

FIG. 5 illustrates the components of option module connector 102 according to an example embodiment.

### DETAILED DESCRIPTION

The invention now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. One skilled in the art may be able to use the various embodiments of the invention.

Embodiments disclosed herein provide an architecture that reduces shear strain on a board-to-board (BTB) connection between an option module and a motherboard in an IHS chassis. The chassis may have different form factors, such as desktop, mini tower, small form factor, etc. The option module is used to incorporate optional features into the IHS chassis. This may include, for example, port module cards that add customer-selected ports such as HDMI, USB, Ethernet, or other ports or external connections. Typically, such option modules are mounted within the chassis and expose a desired port connection through an opening in a chassis wall (e.g., a USB port on the back wall of a chassis). Existing option modules are mechanically connected to the chassis wall using screws, for example, that hold the option modules in place. The screws used in prior option modules provide a rigid connection to the chassis wall that absorbs the strain induced by plugging/unplugging connectors to the port. As a result, the option modules are required to have two rigid connections. The first rigid connection is at the rear wall (e.g., where the option module functionality is exposed to a user), and the second rigid connection is at the connector interface (e.g., the connection between the option module and a motherboard). These rigid connections cause a tolerance problem. For example, if the distance between the chassis rear wall and the motherboard connector differs from the distance designed into the option module, then sheer forces will be applied to the option module-motherboard connection (e.g., a board-to-board connector) once the option module is installed. This can result in damage to the connector, which will impact option module functionality and operation. Legacy option modules were connected to the motherboard via a cable and, therefore, only had a single rigid connection at the rear wall.

Existing option modules use cable connections between the option module cards and the motherboard. These cables provide flexibility. Once the prior option module was attached to the chassis wall, a cable could connect between any area on the module card to an area on the motherboard. However, a BTB connection has several advantages over a cabled connection, including increased signal integrity, higher density of connections within a smaller space, improved electrical performance due to shorter signal paths, greater mechanical stability, and easier assembly in compact systems by eliminating the need for separate cables and allowing for stacking of circuit boards directly on top of each other. BTB connections are limited by requiring a precise alignment to avoid strain on the connectors. The architecture disclosed herein provides a tolerance bracket on the option module that allows for proper connector alignment without inducing sheer strain on a BTB connector.

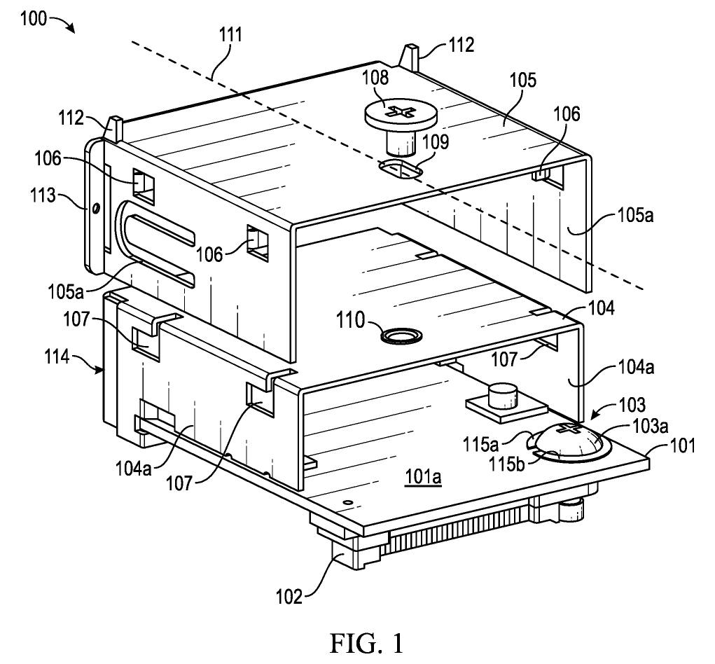

FIG. 1 is a partially exploded view of an option module 100 according to an example embodiment. Printed circuit board assembly (PCBA) 101 contains all the electronic components (not shown) needed to make the option module 100 function as required. These components may include, for example, physical ports and connectors, controller chips, integrated circuits (ICs), data and power traces, and power regulation devices. A connector 102 mounted on the bottom surface of PCBA 101 is configured to mate with a corresponding BTB connector on a motherboard. Connector 102 may be a male or female connector with any number and pattern of pins as appropriate to attach to the connector on the motherboard. A metal fastener 103, such as a screw, is positioned through PCBA 101 and connector 102. Fastener 103 is configured to engage a hole in the motherboard connector. When option module 100 is mounted within a chassis, fastener 103 is tightened to lock the BTB connector ends together.

The components on PCBA 101 are protected by an option module bracket 104. A tolerance bracket 105 is configured to fit over and around the sides of option module bracket 104. In the illustrated embodiment, tabs 106 are formed in the sidewalls 105a of tolerance bracket 105. Tabs 106 are bent inwards and are configured to engage slots 107 formed in the sidewalls 104a of option module bracket 104. Tabs 106 are lowered into slots 107 and are then moved forward, which secures tolerance bracket 105 vertically to option module bracket 104.

A screw 108 passes through a slot 109 in tolerance bracket 105 and into a hole 110 in option module bracket 104. Screw 109 engages either threads in hole 110 or a nut (not shown) below hole 110. When screw 109 is loose, tolerance bracket 105 can move longitudinally relative to option module bracket 104 along axis 111. When tolerance bracket 105 is in a desired position relative to option module bracket 104, screw 108 is tightened to lock the brackets 104, 105 together.

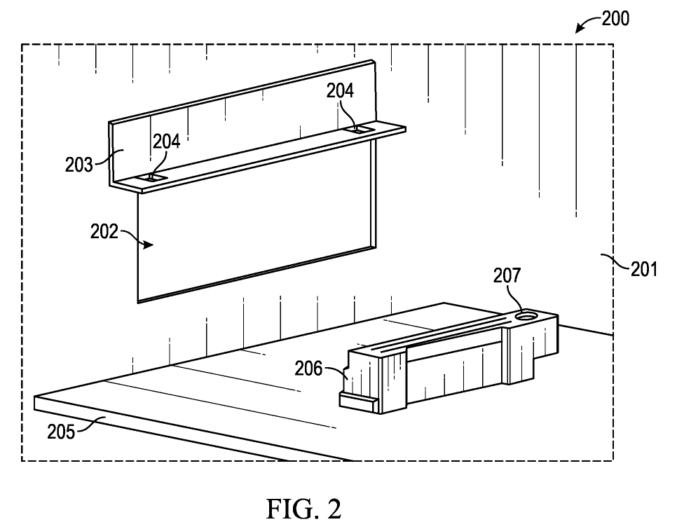

Tolerance bracket 105 has hooks 112 that are configured to engage a mounting bracket (e.g., bracket 203, FIG. 2) on a chassis. Tabs 113 on tolerance bracket 105 are positioned to rest against a chassis wall (e.g., wall 201, FIG. 2) when the option module 100 is installed. Typically, option module 100 has a panel side or face 114 that is exposed to users through the chassis wall.

Two metal contacts 115a, 115b are located on the top surface 101a of PCBA 101 and positioned generally below the head 103a of fastener 103. When fastener 103 is tightened down, such as to lock connector 102 to a corresponding connector on a motherboard, fastener head 103a will touch both contacts 115a, 115b. This will cause fastener head 103ato create an electrical short between contacts 115a, 115b. As disclosed herein, this electrical short may be used as a switch to close an electrical circuit that detects or indicates when fastener 103 has been tightened.

FIG. 2 illustrates a portion of an IHS chassis 200 having a wall 201, such as a rear wall of the chassis. An opening 202 is formed in wall 201. Opening 202 is configured to receive the panel side 114 of option module 100 (FIG. 1). A mounting bracket 203 is attached to wall 201 above the opening 202. Mounting bracket 203 has holes 204 that are configured to receive the hooks 112 on option module 100 (FIG. 1). Chassis 200 further includes a motherboard 205 and a motherboard connector 206. When an option module is installed on wall 201, the option module connector 102 (FIG. 1) attaches to motherboard connector 206.

Connector 206 has a number of pins or pin receptacles that are adapted to mate with connector 102 (FIG. 1). When option module connector 102 is attached to motherboard connector 206, connector fastener 103 fits in opening 207. Fastener 103 may then be tightened to lock connectors 102 and 206 together. For example, fastener 103 may be a screw or a bolt and opening 207 may be a threaded hole adapted to receive the screw or bolt. Threads on fastener 103 engage treads in hole 207, which mates connector 102 securely against connector 206 when fastener 103 is tightened.

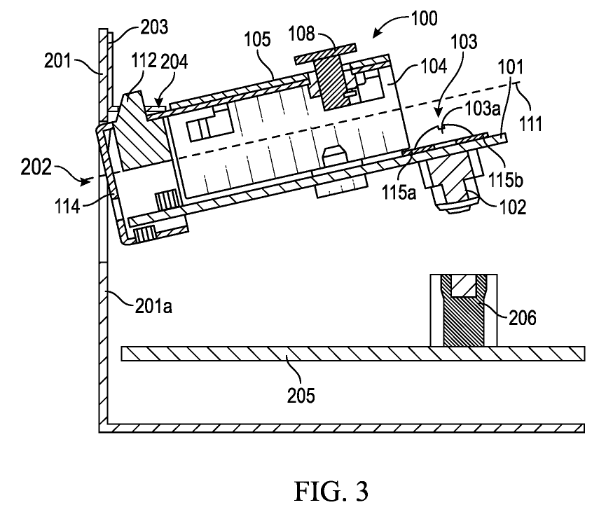

FIG. 3 illustrates a cross section view of an option module (e.g., option module 100, FIG. 1) being installed in a chassis (e.g., chassis 200, FIG. 2) according to one embodiment. The option module 100 is angled toward opening 202 in wall 201. The panel side 114 of option module 100 is passed through the opening 202. The option module 100 is then lifted upward so that hooks 112 engage holes 204 in mounting bracket 203. During the initial installation steps screw 108 is loose and tolerance bracket 105 is able to move longitudinally relative to option module bracket 104 along axis 111.

Once the hooks 112 are in place, the option module 100 is rotated so that connector 102 attaches to motherboard connector 206. Option module bracket 104 moves along axis 111 within tolerance bracket 105 as necessary for connector 102 to align and mate with connector 206 without introducing any sheer forces on the connectors. The ability of option module bracket 104 to move within tolerance bracket 105 during installation provides an auto-adjusting tolerance compensation for variations between different chassis designs. Bracket 104 is rigidly attached to PCBA 101, and tolerance bracket 105 is rigidly attached to a chassis wall. In different chassis models, the thickness of wall 201 may vary. The tolerance bracket architecture disclosed herein does not rely on knowing the wall thickness, but instead only requires that holes 204 on bracket 203 are positioned accurately for hooks 112 in order to secure the tolerance bracket 105 to wall 201.

The option module 100 is installed with screw 108 in a loose configuration, so that the option module bracket 104 is able to freely slide back-and-forth within tolerance bracket 105 relative to the chassis wall. This allows connector 102 to properly align with 206 without inducing sheer forces caused by tolerance stack-up between mated connectors 102/206 and walls 114/201. Once connectors 102, 206 are attached, fastener 103 may be tightened to lock the connectors together.

As shown in the example of FIG. 3, contacts 115a, 115b are located under the head 103a of fastener 103. When fastener 103 is eventually engaged with connector 206 and tightened, fastener head 103a will lower and touch both contacts 115a, 115b, which creates an electrical short between the contacts 115a, 115b.

The amount of free play between option module bracket 104 and tolerance bracket 105 can easily be modified by increasing the length of slot 109 (FIG. 1). In an example embodiment, slot 109 may allow for +/-1.0 mm of movement between option module bracket 104 and tolerance bracket 105. After the connectors 102, 206 are attached and fastener 103 is tightened, screw 108 can be tightened to lock the option module bracket 104 and tolerance bracket 105 together and prevent additional movement.

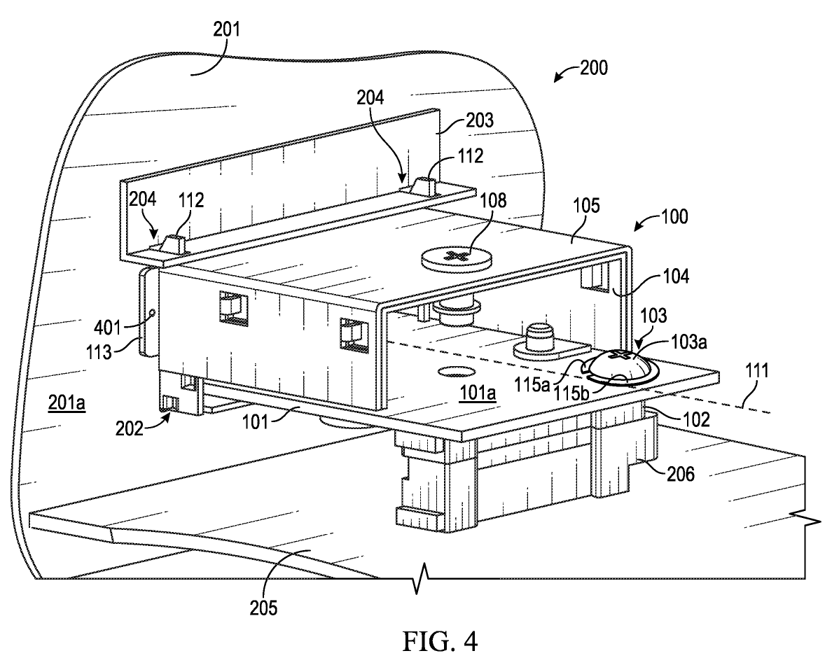

FIG. 4 is an isometric view of the inside of chassis 200 showing the option module 100 installed. Hooks 112 are engage in holes 204, which prevents any further movement of tolerance bracket 105 away from wall 201. When option module 100 is in position, tabs 113 are flush against the inside surface 201a of wall 201, which prevents any further movement of tolerance bracket 105 toward wall 201. Accordingly, between hooks 112 and tabs 113, tolerance bracket 104 is fully constrained along axis 111. Option module bracket 104 is constrained along axis 111 after connector 102 is attached to connector 206. Once option module bracket 104 and tolerance bracket 105 are in place, tightened screw 108 prevents any further movement of the components.

Connector fastener 103 has been tightened and engages opening 207 (FIG. 2) to hold connectors 102, 206 securely together. Fastener 103 is tightened until head end portion 103a is flush with PBCA top surface 101a and touching both contacts 115a, 115b.

In some configurations, option module 100 may need to be grounded to chassis 200 to prevent electromagnetic interference (EMI). FIG. 4 illustrates an EMI grounding point 401 on tab 113. Grounding point 401 may be, for example, a dimple on tab 113 that ensures metal-to-metal contact between option module 100 and wall 201.

Option module 100 uses a dense, high-speed BTB connector 102 in some embodiments. This connector provides optimal signal integrity with high-speed functionality. Such high-speed connectors require extra assurance that option module detection is only made when the module connector 102 is fully seated to the motherboard connector 206. Option module detection is based off an active low signal (for example “Screw_Detect_N”) on the motherboard/module connectors that when its voltage is held low to ground (GND), it allows the system to detect when an option module has been installed. In some cases, due to limited space on both the option module and motherboard PCBs, the BTB connector has only one pin available for module detection support. Typically, using one pin does not provide sufficient reliability that an option module 100 is correctly seated to the motherboard 205 before the system detects the option module.

The embodiments disclosed herein use plated contacts on a connector screw hole to ensure a mechanically secure connection between an option module PCB to a motherboard PCB. A plated screw hole is added to the option module PCB, which allows for a mechanical screw to securely fasten the BTB connectors between the option module and the motherboard.

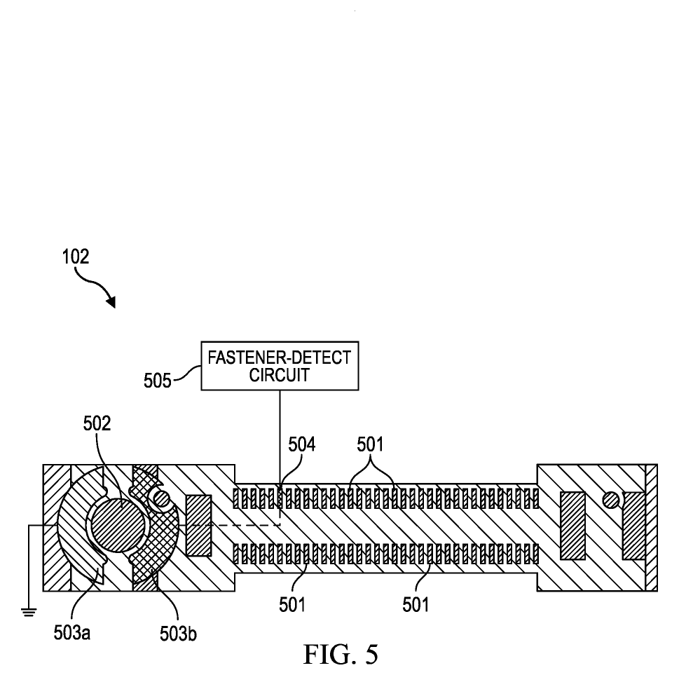

FIG. 5 illustrates the components of option module connector 102 according to an example embodiment. Connector 102 has a number of pins or pin receptacles/sockets 501 (i.e., may be a male and/or female connector). Connector 102 also has a fastener hole 502 adapted to receive a fastener 103 (a screw or bolt, for example) that is used to lock the BTB connectors together. This fastener is used to mechanically secure the connector and to electrically detect when the option module 100 is installed on a motherboard 205 via a BTB connector 102/206.

It is standard industry practice to use mounting screws to securely mount a motherboard to a chassis. In order to provide a secure mount without damaging the PCB surface with a mounting screw, plated through holes are typically placed on the surface of the motherboard PCB. Generally, these mounting holes have a pad exposed beneath the solder mask so that the mounting point can be electrically connected to a signal on the PCB. Because floating metal can be a source of EMI, this pad is typically electrically connected to either chassis ground (GND) or digital GND on the PCB.

To use the mounting screw for option module detection, the screw pad ring on the PCB cannot be solely connected to GND or a screw detect signal will always be held low on the option module and, therefore, the option module will quickly be detected as present by the motherboard during installation. Instead, the mounting hole pad ring on the PCB must be split into two isolated contacts where one contact is tied to a signal pin (+) on the connector and the other contact is tied to GND (-).

As illustrated in FIG. 5, plated contacts 503a, 503b are formed around the mounting hole 502 used with connector 102. Contacts 503a, 503bmay be formed on the top surface of an option module PCB, such as contacts 115a, 115b (FIG. 1). Contact 503a is tied to ground. Contact 503bis tied to a Screw_Detect_N pin 504 on connector 102. In an example system, a signal from an active low Screw_Detect_N circuit 505 is pulled-high on the motherboard side to detect that an option module has not been installed. . Only after installing the option module onto the motherboard’s BTB connector and securing the option module's mounting screw to the BTB connector, the active low Screw_Detect_N signal will be shorted to GND via the screw hole's split pad ring (i.e., contacts 503a, 503b), which will then cause the option module to be detected by the motherboard.

This configuration provides a dual authentication method electrically detecting any PCB-to-PCB connection through the use of a single mechanical screw or fastener. Using this method, the mounting screw not only mechanically secures an option module to a motherboard in the present example, but it also provides a dual detection method that indicates to the system when a mounting screw is present and establishes a secure electrical data connection to the motherboard once the screw is secured. This provides a foolproof method for providing enhanced reliability and functionality that an option module will not be detected by a motherboard until the option module is properly seated with the mounting screw fully fastened. This is particularly important for any high-speed BTB connections due to signal integrity concerns.

The single screw is multi-purposed and provides attachment of the option module to a chassis/motherboard, ensures electrical mating of the connector components, and provides perpendicular mechanical force retention of the option module to the motherboard. The screw-detect feature ensures foolproof factory assembly to enable all these multi-purposed benefits. The integrated screw detection design with the contact pads 503a, 503b on the top side of the option module PCB avoids false-positive detections.

While the example illustrated herein is directed to installing an option module in a chassis, the single screw detection method can also be applied to any type of daughterboard or key mounting screw on a motherboard that requires detection. Other examples include, without limitation: heat sinks, solid-state drives (SSD), CPU fans, PCB riser cards, etc. With the dual authentication screw-detection signal being electrically connected to key screws mounted on a motherboard, this ensures that key system components (i.e., mechanical, electrical, and thermal components) are fully seated during factory installations and/or after being serviced in the field. This type of detection method prevents potential hardware repair dispatches from occurring due to quality issues or concerns should any mounting screws or key screws show a false present detection or loosen due to shock/vibration testing or during shipping.

When the screw-detect signal is not detected, that is not pulled low to GND, a critical error message may flag that a key system component is not fully seated within the system.

In one arrangement, a module for an information handling system comprises a circuit board having a first side and a second side opposite the first side. A hole is formed in the circuit board. The hole has a first opening on the first side of the circuit board. A first contact is adjacent to the first opening, and a second contact is also adjacent to the first opening and spaced apart from the first contact. A module connector is attached to a bottom surface of the circuit board. The module connector has a plurality of pins or sockets. The first contact is electrically connected to a selected pin or socket. The second contact is electrically connected to ground.

A fastener extends through the hole. The fastener has a head end located on the first side of the circuit board. The head end touches both the first contact and the second contact when the fastener is tightened. The head end is adapted to cause an electrical short between the first contact and the second contact when touching both the first contact and the second contact.

The selected pin or socket is electrically connected to ground when the head end is touching both the first contact and the second contact. The fastener has a threaded end opposite the head end, the threaded end adapted to attach to a motherboard connector.

In an example configuration, an information handling system comprises a motherboard with a motherboard connector and a module. The module includes circuit board having a first side and a second side opposite the first side. A hole in the circuit board has a first opening on the first side of the circuit board. A first contact is located adjacent to the first opening, and a second contact is also located adjacent to the first opening and spaced apart from the first contact. A module connector is coupled to the motherboard connector. The first contact is electrically connected to a selected pin or socket on the module connector. The second contact is electrically connected to ground.

The information handling system also includes a fastener-detect socket or pin on the motherboard connector. The fastener-detect socket or pin adapted to electrically connect to the selected pin or socket on the module connector. A fastener-detect circuit is coupled to the fastener-detect socket or pin. The fastener-detect circuit is configured to hold the fastener-detect socket or pin at a high signal voltage.

A fastener extends through the hole. The fastener has a head end located on the first side of the circuit board. The head end touches both the first contact and the second contact. The head end is adapted to cause an electrical short between the first contact and the second contact when touching both the first contact and the second contact. The selected pin or socket is electrically connected to ground when the head end is touching both the first contact and the second contact.

The fastener has a threaded end opposite the head end. The threaded end is adapted to attach the module connector to the motherboard connector.

In another arrangement, an IHS includes a motherboard connector mounted on a motherboard. The motherboard connector has a first detection contact. An IHS component includes a component connector having a second fastener-detect contact. The second detection contact is adapted to electrically connect to the first detection contact on the motherboard connector. A component fastener has a head end. The component fastener is disposed within a hole in the IHS component and configured to attach the component connector to the motherboard connector. A first fastener contact is positioned adjacent to the hole and is electrically coupled to the motherboard connector. The first contact is electrically connected to a selected pin or socket on the module connector. A second fastener contact is positioned adjacent to the hole and spaced apart from the first contact. The second fastener contact is electrically connected to ground. The first fastener contact is electrically connected to ground when the head end is touching both the first fastener contact and the second fastener contact.

The IHS further includes a motherboard controller configured to monitor a voltage signal on the first detection contact. The motherboard controller may be a Platform Controller Hub (PCH) or an Embedded Controller (EC). The component may be selected from the group consisting of: a heatsink, a cold plate, a solid-state drive, a CPU fan, a riser card, and an option module.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated that the conception and specific embodiment disclosed may be readily utilized as a basis for modifying or designing other structures for carrying out the same purposes of the present invention. It should also be realized that such equivalent constructions do not depart from the invention set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

What is claimed is:

1. A module for an information handling system, comprising:
a circuit board having a first side and a second side opposite the first side;
a hole in the circuit board, the hole having a first opening on the first side of the circuit board;
a first contact adjacent to the first opening;
a second contact adjacent to the first opening and spaced apart from the first contact; and
a module connector attached to a bottom surface of the circuit board, the module connector having a plurality of pins or sockets, wherein the first contact is electrically connected to a selected pin or socket.

2. The module of claim 1, wherein the second contact is electrically connected to ground.

3. The module of claim 1, further comprising:
a fastener extending through the hole, the fastener having a head end located on the first side of the circuit board.

4. The module of claim 3, wherein the head end is touching both the first contact and the second contact.

5. The module of claim 3, wherein the head end is adapted to cause an electrical short between the first contact and the second contact when touching both the first contact and the second contact.

6. The module of claim 3, wherein the selected pin or socket is electrically connected to ground when the head end is touching both the first contact and the second contact.

7. The module of claim 3, wherein the fastener has a threaded end opposite the head end, the threaded end adapted to attach to a motherboard connector.

8. An information handling system, comprising:
a motherboard having a motherboard connector; and
a module, comprising:
a circuit board having a first side and a second side opposite the first side;
a hole in the circuit board, the hole having a first opening on the first side of the circuit board;
a first contact adjacent to the first opening;
a second contact adjacent to the first opening and spaced apart from the first contact; and
a module connector coupled to the motherboard connector, wherein the first contact is electrically connected to a selected pin or socket on the module connector.

9. The information handling system of claim 8, further comprising:
a fastener-detect socket or pin on the motherboard connector, the fastener-detect socket or pin adapted to electrically connect to the selected pin or socket on the module connector.

10. The information handling system of claim 9, further comprising:
a fastener-detect circuit coupled to the fastener-detect socket or pin, the fastener-detect circuit configured to hold the fastener-detect socket or pin at a high signal voltage.

11. The information handling system of claim 8, wherein the second contact is electrically connected to ground.

12. The information handling system of claim 8, further comprising:
a fastener extending through the hole, the fastener having a head end located on the first side of the circuit board.

13. The information handling system of claim 12, wherein the head end is touching both the first contact and the second contact.

14. The information handling system of claim 12, wherein the head end is adapted to cause an electrical short between the first contact and the second contact when touching both the first contact and the second contact.

15. The information handling system of claim 8, wherein the selected pin or socket is electrically connected to ground when the head end is touching both the first contact and the second contact.

16. The information handling system of claim 8, wherein the fastener has a threaded end opposite the head end, the threaded end adapted to attach the module connector to the motherboard connector.

17. An information handling system (IHS), comprising:
a motherboard connector mounted on a motherboard, the motherboard connector having a first detection contact; and
an IHS component, comprising:
a component connector having a second fastener-detect contact, the second detection contact adapted to electrically connect to the first detection contact on the motherboard connector;
a component fastener having a head end, the component fastener disposed within a hole in the IHS component and configured to attach the component connector to the motherboard connector;
a first fastener contact positioned adjacent to the hole and electrically coupled to the motherboard connector, wherein the first contact is electrically connected to a selected pin or socket on the module connector; and
a second fastener contact positioned adjacent to the hole and spaced apart from the first contact, the second fastener contact electrically connected to ground;
wherein the first fastener contact is electrically connected to ground when the head end is touching both the first fastener contact and the second fastener contact.

18. The IHS of claim 17, further comprising:
a motherboard controller configured to monitor a voltage signal on the first detection contact.

19. The IHS of claim 18, wherein the motherboard controller is a Platform Controller Hub (PCH) or an Embedded Controller (EC).

20. The IHS of claim 17, wherein IHS component is selected from the group consisting of: a heatsink, a cold plate, a solid-state drive, a CPU fan, a riser card, and an option module.
